(19) United States
(12) Patent Application Publication
(10) Pub. No.: US 2021/0153338 A1
(43) Pub. Date: May 20, 2021

(54) THERMALLY CONDUCTIVE GRAPHENE-BASED MATERIAL AND METHOD FOR MANUFACTURING THE SAME

(71) Applicant: SHT SMART HIGH-TECH AB, Göteborg (SE)

(72) Inventors: Johan LIU, VÄSTRA FRÖLUNDA (SE); Nan WANG, MÖLNDAL (SE)

(73) Assignee: SHT SMART HIGH-TECH AB, Göteborg (SE)

(21) Appl. No.: 17/044,909

(22) PCT Filed: Apr. 3, 2018
(86) PCT No.: PCT/SE2018/000009

§ 371 Date: Oct. 2, 2020

(51) Int. Cl. H05K 1/02; C01B 32/205; C01B 32/198

(52) U.S. Cl. CPC H05K 1/0209; C01B 32/205; C01B 2204/24; C01B 2204/32; C01B 32/198

(57) ABSTRACT

The invention relates to a heat spreading structure comprising: a first substrate layer; a second substrate layer; and a thermally conductive graphite film sandwiched between the first and second substrate layers, wherein the graphite film comprises a plurality of graphene layers having a turbostratic alignment between adjacent graphene layers. The invention also relates to a method for manufacturing a graphite film for a heat spreading structure.

### FIELD OF THE INVENTION

The present invention relates to a thermally conductive graphene based material and to a method for manufacturing such a material.

### BACKGROUND OF THE INVENTION

The development of electronics towards miniaturization and multi-functionalization causes severe thermal dissipation issues that greatly threaten the performance and reliability of electronic devices, batteries and many other high power systems. One way to solve this problem is to integrate heat spreading materials that can efficiently transport excessive heat away from power devices, thereby reducing the operating temperature of the system. To achieve this, the heat spreading material needs to have an ultra-high thermal conductivity in addition to very thin, flexible and robust structures to match the complex and highly integrated nature of power systems. So far, however, most of commercially available high thermal conductivity materials, like copper, aluminum, and artificial graphite, are not good enough in satisfying these demands.

Currently, the main thermal management and heat spreading material on the market is the pyrolytic graphite sheets (PGS) fabricated from polyimide film (PI) and graphite film made from the natural graphite. The first process cannot make too large grain size due to its intrinsic issue with the nucleation and growth process. The natural graphite films often contain too much defects making them with low thermal conductivity. As the electronics and power devices continue to become more functional, the market is therefore in desperate need of a graphite film with higher thermal conductivity that is beyond todays existing material.

Graphene has recently been paid great amount of attention due to its superior intrinsic physical properties. Particularly, the ultrahigh thermal conductivity of single layer graphene (about 3300-5300 W/mK) is one of the most interesting properties that may offer potential solutions to the above mentioned thermal management issues. Previous studies have shown that the surface temperature of hotspots can be successfully decreased up to 13° C. by simply applying a single layer graphene grown by chemical vapor deposition method. Despite the remarkable cooling performance of single layer graphene, there are many other challenges that limit its wide application in electronic systems, such as complexity of transfer process, high cost, small area, and relatively low heat flux allowed to be dissipated. Therefore, for real applications, it is essential to develop novel graphene based structures that possess both extremely high thermal conductivity and other properties such as free-standing and large area structure, easy handling, robustness and potential to be mass producible.

### SUMMARY

In view of above-mentioned and other drawbacks of the prior art, it is an object of the present invention to provide an improved heat spreading material and a method for manufacturing such a heat spreading material.

According to one embodiment of the invention, there is provided a heat spreading structure comprising: a first substrate layer; a second substrate layer; and a thermally conductive graphite film sandwiched between the first and second substrate layers, wherein the graphite film comprises a plurality of graphene layers having a turbostratic alignment between adjacent graphene layers.

In the present context, graphene layers having a turbostratic alignment are adjacent graphene layers which have an offset with respect to the regular graphite structure. In other words, one graphene layer is shifted with respect to an adjacent layer to prevent formation of a regular graphite lattice structure.

It has been found that a graphite film with turbostratic alignment between adjacent graphene layers exhibits a greatly improved in-plane thermal conductivity in comparison to known graphene-based and graphite heat spreading material. In the present disclosure, the thermal conductivity discussed will refer to the in-plane thermal conductivity of the materials unless specifically stated otherwise. The improved thermal conductivity can be explained by a reduced phonon scattering as a result of weaker interlayer binding for the turbostratic structure. In comparison, the strong interlayer binding between ordered graphene layers can lead to severe phonon interfacial scattering and reduce thermal conductivity of graphite films.

According to one embodiment of the invention a thickness of the graphite film is preferably between 0.5 μm and 5 μm. Studies of the graphite film have shown that phonon scattering increases with increasing thickness of the graphite film. Thickness within the range of 0.5 μm and 5 μm also shows a high degree of turbostratic-stacking graphene higher than 20%. A thickness above 10 μm can reduce the amount of turbostratic graphene to be less than 5%. On the other hand, a certain thickness of the graphite film is required to achieve meaningful thermal conduction. In view of this, it has been found that a suitable thickness for the graphite film is in the range of 0.5 μm to 5 μm.

According to one embodiment of the invention a thickness of the first and the second substrate layer may be between 50 μm and 10 mm. Hereby, a large number of different types of substrates and substrate materials are possible for integration with the thermally conductive graphite film, paving the way for a wide range of applications.

According to one embodiment of the invention, the graphite film advantageously consists of at least 30 vol % turbostratic structure. Even though the aim is to provide a material which has a percentage of turbostratic material which is as high as possible, improved thermal properties can be seen already in a graphite structure where 30% of the graphene material exhibits a turbostratic alignment.

According to one embodiment of the invention, the graphite film may advantageously consist of graphene flakes and have an average lateral size in the range of 2-100 μm. The lateral size of the graphene flakes in turn determines the amount of grain boundaries in the graphite material. Since the grain boundaries can greatly increase the phonon scattering and thereby decrease thermal conductivity, it is desirable to increase the lateral size of the graphene flakes to reduce the amount of grain boundaries, thereby improving thermal conductivity.

According to one embodiment of the invention the graphite film may have a thickness below 1 μm and consists of at least 40% turbostratic structure. Studies of the described material have found that an in-plane thermal conductivity of the graphite film is higher than 3000 W/mK.

According to one embodiment of the invention, the first and/or the second substrate may be a thermally conductive metal layer comprising a metal selected from the group comprising Ti, Cr, Co, Mg, Li, Cu, Al, Ni, Sn, steel, and alloys thereof. Thereby, a heat spreading structure can be formed which can be used in devices such as heat exchanges, heat pipes and other types of heat transfer devices. The in-plane thermal conductivity of the graphite film can then be combined with the omnidirectional thermal conductivity of the metal layer.

According to one embodiment of the invention, the first and/or the second substrate layer may comprise a printed circuit board, PCB, and/or a plastic material. Moreover, first and/or the second substrate layer may comprise a functional paper material. Accordingly, laminate structures having many different layers and material combinations can be formed where the thermally conductive graphite film acts as a heat spreading layer. The graphite film may for example be employed as a heat spreading material in electronic applications.

According to a second aspect of the invention, there is provided a method for manufacturing a graphite film for a heat spreading structure. The method comprising: fabrication of graphene oxide flakes; forming a large-size graphene oxide suspension; shearing of the graphene oxide flakes to reduce the thickness of the graphene oxide flakes; dry-bubbling fabrication of graphene oxide films; performing graphitization by thermal annealing and pressing of the film of graphene oxide flakes, thereby providing a graphite film comprising graphene layers having a turbostratic alignment between adjacent graphene layers. By means of the described method the graphite film having the properties discussed above can be formed.

According to one embodiment of the invention, shearing is performed to provide graphene flakes having a lateral size in the range of 2-100 μm, and a thickness less than 1 nm. The large lateral size and small thickness is essential for increasing the grain size and turbostratic-stacking graphene in the final graphene films. Therefore, it can achieve an in-plane thermal conductivity higher than 3000 W/mK.

According to one embodiment of the invention, a concentration of graphene oxide (GO) flakes in the graphene oxide suspension may advantageously be in the range of 1 to 40 mg/ml. The concentration of the fabricated GO suspension has a strong effect on the self-assembly process due to its ability to form liquid crystal phases that take place at certain concentrations. Also, the concentration of the GO suspension will determine the efficiency of the film production.

Moreover, the fabrication of graphene oxide flakes is may advantageously be controlled to provide graphene oxide flakes having an oxygen concentration in the range of 20 to 70 wt %. An appropriate GO oxygen concentration is essential for both the self-assembly process and the final thermal performance of the graphite film. For example, the large amount of oxygen functional groups on the basal plane of GO is the main reason for GO to form stable aqueous suspension. The lower oxygen content, the worse stability of the suspension has. In view of this, it has been found that it is preferable to form graphene oxide flakes having an oxygen concentration in the range of 20 to 70 wt %.

According to one embodiment of the invention, there is provided a method for manufacturing a heat spreading structure comprising: providing a substrate; attaching a turbostratic graphite film manufactured according to any of the aforementioned embodiments to a surface of the first substrate; and attaching a second substrate to the turbostratic graphite film to form a laminate structure comprising the turbostratic graphite film sandwiched between the first substrate and the second substrate.

Moreover, the turbostratic graphite film may advantageously be bonded to the first and/or second substrate to form an interface between the graphite film and the substrate having a high thermal conductivity over the interface. In applications where the substrate is thermally conductive and where it is desirable to achieve thermal transfer from the graphite film to the substrate, the interface is preferably tailored to optimize heat transfer across the interface.

Additional effects and features of the second aspect of the invention are largely analogous to those described above in connection with the first aspect of the invention.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIG. 1 schematically illustrates a heat spreading structure according to an embodiment of the invention; and

FIG. 2 is a flow chart outlining the general steps of a method of manufacturing a graphite film for a heat spreading structure according to an embodiment of the invention.

### DETAILED DESCRIPTION OF EXAMPLE EMBODIMENTS

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person. Like reference characters refer to like elements throughout.

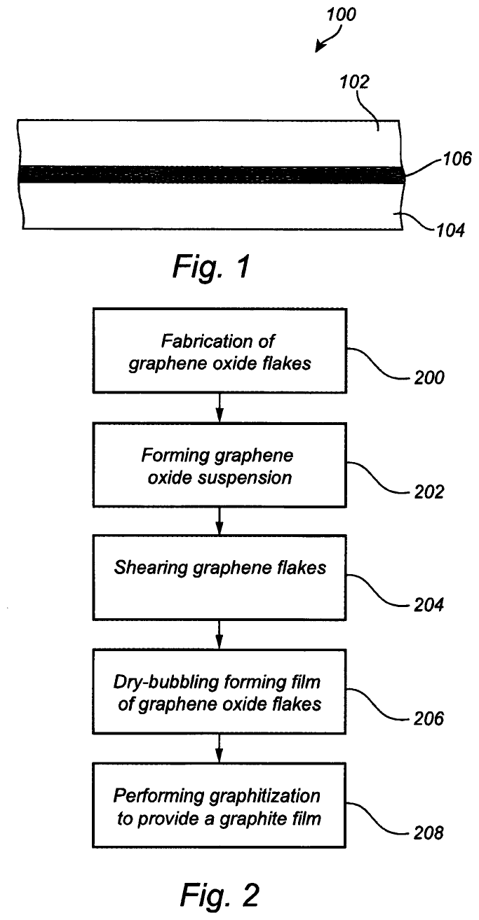

FIG. 1 schematically illustrates a heat spreading structure 100 according to an embodiment of the invention. The heat spreading structure 100 comprises: a first substrate layer 102, a second substrate layer 104, and a thermally conductive graphite film 106 sandwiched between the first and second substrate layers 102, 104, wherein the graphite film 106 comprises a plurality of graphene layers having a turbostratic alignment between adjacent graphene layers.

FIG. 2 is a flow chart outlining the general steps of a method of manufacturing a graphite film 106 for a heat spreading structure according to an embodiment of the invention. The method comprises dry-bubbling fabrication 200 of graphene oxide flakes, forming 202 a graphene oxide suspension, shearing 204 of the graphene oxide flakes to reduce the size of the graphene oxide flakes; forming 206 a film of graphene oxide flakes; and performing graphitization 208 by thermal annealing and pressing of the film of graphene oxide flakes, thereby providing a graphite film comprising graphene layers having a turbostratic alignment between adjacent graphene layers.

In the following, an example embodiment of the method will be described in further detail.

Graphene oxide (GO) was prepared by following a modified Hummers method reported in literature. In an example embodiment, 5 g of expanded graphite flakes, 3.75 g of NaNO₃, and 200 mL of concentrated H₂SO₄ were mixed at 0° C. 15 g of KMnO₄ was slowly added into the mixture within about 1 h, followed by stirring for 1 h in an ice water bath. After that, the ice water bath was replaced by oil bath, in which the temperature was controlled in the range of 42˜50° C., and kept stirring for 3 h. Then, 400 mL of 5 wt % H₂SO₄ was added into the solution. The resultant mixture was further stirred for 1 h at 98° C. The reaction was terminated by adding 15 mL of 30 wt % H₂O₂ into the above solution when the temperature was lowered to 80° C. The mixture was precipitated at room temperature and followed by centrifuging and washing with deionized water until the pH value was in the range of 5-9.

The obtained colloid was dispersed into certain amounts of deionized water to obtain a GO solution with certain concentrations. The exfoliation of GO was carried out by using a high-shear mixer. After shear mixing, the obtained GO suspension was centrifuged at 5000-8000 rpm for 30-50 min to remove all the big particles as well as GO with large thickness, giving a purified large-area and thin GO dispersion.

A plain substrate was cleaned by isopropanol solution to completely remove the impurities, and then washed with deionized water. After drying, a dismountable frame with the same size as the substrate was fixed onto the substrate surface. A certain volume of the above described purified GO suspension was uniformly spread onto the substrate under mildly shaking. The substrate was transferred onto a pre-balanced heating board with temperature in the range of 80 to 120° C. to dry the GO solution. After drying, a certain volume of liquid nitrogen was slowly added to the top surface of the film until the film completely separated from the substrate, here referred to as dry-bubbling. By adjusting the concentrations and volumes of the GO suspension, graphene films (GFs) with different thicknesses can be fabricated.

Graphene films were subsequently fixed between two pieces of polished graphite plates and annealed in an electrical furnace at different temperatures for 24-72 h. The heating rate of the furnace was 1000° C./h, and the cooling rate was 50° C./h. After thermal annealing, the films were pressed by a hydraulic pressing equipment under 300-600 MPa in a time period of 5-120 min to remove air pockets and to obtain ultimate densified GFs.

Forming thin graphene films with a thickness less than 5 μm is essential for achieving good layer alignment, high degree of turbostratic-stacking graphene, and high density. The dry-bubbling method is developed for achieving this goal. By using liquid nitrogen as the detaching agent, the free water molecules can be frozen immediately at the extremely low temperature and lose its connection with the substrate and the GO film. Also, due to the large liquid-to-gas expansion ratio (1:694 at 20° C.), the liquid nitrogen that penetrated to the bottom surface of GO film can generate a tremendous amount of force to separate the film completely from the substrate. The use of liquid nitrogen also wouldn't leave any residuals or wet the film, showing the high cleanness of the described process.

In order to obtain GFs with outstanding thermal conductivities along the in-plane direction, large grain sizes and low interlayer binding energy are required for GFs because heat conduction in graphene is essentially governed by phonon transport inside of the sp² bonded hexagonal carbon lattice as well as phonon interfacial scattering. To optimize the grain size and film alignment in final GFs, the structure of initial GO sheets was carefully tailored with regard to lateral sizes and thickness of the initial GO sheets, concentrations of the suspension and oxygen contents. In brief, a large lateral size in the range of 2-100 μm, and a small thickness of <1 nm and high oxygen content of up to 70 wt % can improve the layer coalescence and alignment in the following graphitization process. To minimize the adverse effect of thickness increase to phonon transport and to improve the flexibility, defect-free, highly uniform, ultrathin and free-standing film structures with a thickness of 800 nm were manufactured.

The described free-standing and ultrathin GF fabrication process has many advantages, such as simplicity, cleanliness, high efficiency and unlimited film size, showing great potential for large-scale production.

The fabricated GO films were thermally reduced at a temperature of 2850° (GF-2850° C.) to completely remove oxygen and enhance the grain size of the GFs. In GF-2850° C., most of the overlaps between neighboring graphene sheets were eliminated, and the size of smooth features largely increased from 1.5 to 16 μm, which is almost three times larger than the original size of the GO sheets.

In conclusion, the long term thermal reduction at 2850° C. exhibits many advantages, such as: (i) simplicity, since the deoxygenation and graphitization of GFs occur all in one step; (ii) high efficiency on deoxygenation and extending grain size of GFs; (iii) cleanliness, since it avoids the use of toxic chemicals and also prevents the generation of any residuals which may affect the properties of GFs after the reduction; (iv) scalability.

Previous studies have indicated that multilayer graphene can reach the same in-plane thermal conductivity as monolayer graphene if the interlayer binding energy was sufficiently weak. The relatively high degree of turbostratic-stacking graphene in GF-2850° C. can greatly decrease the interaction force between adjacent planes, which significantly reduces the phonon interface scattering and resulted in the ultra-high in-plane thermal conductivity of GF-2850° C. The thickness dependent in-plane thermal conductivity of GF-2850° C. is mainly related to the change of turbostratic-stacking graphene. It has been found that the ratio of turbostratic-stacking graphene decreases with the increase of film thickness. The gradually decreased turbostratic-stacking graphene ratio is induced by the amplified interaction and constraint effects from neighboring layers as the film thickness increases.

Therefore, the large film thickness limited the expansion of the thick film at the temperature-rise period of the graphitization process. In the following graphitization, those layers that remain contacted with each other would be transformed from the incommensurate state of turbostratic-stacking graphene to the commensurate state of AB Bernal stacking.

For GF-2850° C. with a thickness above 10 μm, the material becomes hardly distinguishable from that of bulk graphite, showing a negligible amount of turbostratic-stacking graphene. The recovery of the interlayer binding energy in thick films can deteriorate the free vibration of the individual graphene layer and limit phonon transfer at the in-plane direction. As a result, the in-plane thermal conductivity of GF shows a nearly linear decrease with the reducing of the relative volume of turbostratic-stacking graphene, and levelled off at the average value of bulk graphite (˜2000 W/mK) when thicknesses approach to 10 μm.

In addition to this, it has been found that the size and the amount of air pockets increased with the increase in the film thickness. Due to the strong air impermeability and robust structure of graphene, the removal of air pockets by mechanical pressing becomes much more difficult when the film thickness increases. As a result, the irregular shape of air pockets increased the local phonon scattering by causing the folding and misfits of adjacent graphene layers. These phenomena became more obvious in the thick samples, and thereby, also contributing to the gradual decrease of the thermal conductivity of the GF with the increase of film thickness.

In summary, the developed large-area, free-standing and ultrathin graphene films show great advantages as efficient heat spreading materials in form-factor driven electronics and other high power driven systems.

Even though the invention has been described with reference to specific exemplifying embodiments thereof, many different alterations, modifications and the like will become apparent for those skilled in the art. Also, it should be noted that parts of the method may be omitted, interchanged or arranged in various ways, the method yet being able to perform the functionality of the present invention.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. A heat spreading structure comprising:
a first substrate layer;
a second substrate layer; and
a thermally conductive graphite film sandwiched between the first and second substrate layers, wherein the graphite film comprises a plurality of graphene layers having a turbostratic alignment between adjacent graphene layers.

2. The heat spreading structure according to claim 1, wherein a thickness of the graphite film is between 0.5 μm and 5 μm.

3. The heat spreading structure according to claim 1, wherein a thickness of the first and the second substrate layer is between 50 μm and 10 mm.

4. The heat spreading structure according to claim 1, wherein the graphite film consists of at least 30 vol % turbostratic structure.

5. The heat spreading structure according to claim 1, wherein the graphite film consists of graphene flakes have a lateral size in the range of 2-100 μm.

6. The heat spreading structure according to claim 1, wherein the graphite film has a thickness below 1 μm and consists of at least 40% turbostratic structure.

7. The heat spreading structure according to claim 6, wherein an in-plane thermal conductivity of the graphite film is higher than 3000 W/mK.

8. The heat spreading structure according to claim 1, wherein the first and/or the second substrate is a thermally conductive metal layer comprising a metal selected from the group consisting of Ti, Cr, Co, Mg, Li, Cu, Al, Ni, Sn, steel, and alloys thereof.

9. The heat spreading structure according to claim 1, wherein the first and/or the second substrate layer comprises a printed circuit board, PCB.

10. The heat spreading structure according to claim 1, wherein first and/or the second substrate layer comprises a plastic material.

11. The heat spreading structure according to claim 1, wherein first and/or the second substrate layer comprises a functional paper material.

12. A method for manufacturing a graphite film for a heat spreading structure, the method comprising:
fabrication of graphene oxide flakes;
forming a graphene oxide suspension;
shearing of the graphene oxide flakes to reduce the thickness of the graphene oxide flakes;
dry-bubbling forming a film of graphene oxide flakes;
performing graphitization by thermal annealing and pressing of the film of graphene oxide flakes, thereby providing a graphite film comprising graphene layers having a turbostratic alignment between adjacent graphene layers.

13. The method according to claim 12, wherein shearing is performed to provide graphene flakes having a lateral size in the range of 2-100 μm.

14. The method according to claim 12, wherein a concentration of graphene oxide flakes in the graphene oxide suspension is in the range of 1 to 40 mg/ml.

15. The method according to claim 12, wherein the fabrication of graphene oxide flakes is controlled to provide graphene oxide flakes having an oxygen concentration in the range of 20 to 70 wt %.

16. A method for manufacturing a heat spreading structure comprising:
providing a substrate;
attaching a turbostratic graphite film manufactured according to the method of claim 12 to a surface of the first substrate; and
attaching a second substrate to the turbostratic graphite film to form a laminate structure comprising the turbostratic graphite film sandwiched between the first substrate and the second substrate.

17. The method according to claim 16, wherein the turbostratic graphite film is bonded to the first and/or second substrate.
